(19) United States
(12) Patent Application Publication
(10) Pub. No.: US 2009/0029499 A1
(43) Pub. Date: Jan. 29, 2009

(54) Method for Manufacturing Nitride Semiconductor Light Emitting Element

(75) Inventor: Ken Nakahara, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 12/086,883

(22) PCT Filed: Dec. 20, 2006
(86) PCT No.: PCT/JP2006/325401

§ 371 Date: Jun. 20, 2008

(30) Foreign Application Priority Data
Dec. 21, 2005 (JP) 2005-368157

(51) Int. Cl. H01L 33/00

(52) U.S. Cl. 438/46; 257/E33.025

(57) ABSTRACT

Provided is a method for manufacturing a nitride semiconductor light emitting element. In the method, when an isolation trench for chip isolation and for laser lift-off is formed, a degradation-free nitride semiconductor light emitting element with high luminance can be formed without doing any damages to a light emitting region. In an n type nitride semiconductor layer 2, a step A is formed in a region beyond an active layer 3 looked from a p side. A protective insulating film 6 covers, to a portion of the step A, side surfaces of a part of the n type nitride semiconductor layer 2, the active layer 3, a p type nitride semiconductor layer 4, and a p electrode 5 as well as a part of an upper side of the p electrode 5. With a structure in which side surfaces of a chip are covered with the protective insulating film 6, when the isolation trench for chip isolation and for laser lift-off is formed using etching, the active layer 3 and the like are not exposed to etching gas for a long time.

### TECHNICAL FIELD

The present invention relates to a method for manufacturing a nitride semiconductor light emitting element in which an isolation trench for separating a semiconductor laminated body having a light emitting region and including GaN is formed.

### BACKGROUND ART

Nitride semiconductors, for example, are used for blue LEDs employed as light sources for lighting, backlighting, and the like, and for LEDs, LDs, and the like employed for multicolor. Due to difficulties in manufacturing a bulk single crystal, GaN is grown on a substrate of a different kind, such as sapphire and SiC, by using MOCVD (metal organic chemical vapor deposition). The sapphire substrate has excellent stability in a high temperature ammonia atmosphere in an epitaxial growth process, and therefore, is particularly used as a growth substrate. The sapphire substrate is an insulating substrate. After epitaxial growth, the nitride semiconductor on the sapphire substrate is etched to expose an n type gallium nitride layer. An n type contact is then formed on the etched surface, and two electrodes of a p type and an n type are provided on the same surface side.

In order to separate, into chip-shaped pieces, the nitride semiconductor layer of the above described structure having two electrodes of the p type and the n type provided on the same surface side, an isolation trench is formed on a wafer-shaped nitride semiconductor layer using dry etching.

On the other hand, because the sapphire substrate is an insulating substrate which does not allow conduction, the electrodes cannot be provided to sandwich the sapphire substrate. For this reason, in order to provide a structure having the electrodes facing each other, a method is used in which the sapphire substrate is peeled off to expose the n type gallium nitride layer and the n electrode is formed on the exposed portion. In this way, the n electrode and the p electrode are disposed to face each other.

In the nitride semiconductor device in which the sapphire substrate is peeled off and the n electrode and the p electrode are disposed to face each other as mentioned above, prior to the peeling-off of the sapphire substrate, the isolation trench is formed in the nitride semiconductor layer by using dry etching in order to separate the nitride semiconductor layer into chips (elements).

For example, as shown in FIG. 15, an isolation trench 24 that reaches a sapphire substrate 21 is formed using dry etching in accordance with a size of each element so as to separate, into elements, a GaN buffer layer 22, which is formed on the sapphire substrate 21 and also functions as an isolating layer, and a nitride semiconductor 23, which has a light emitting region and is grown on the GaN buffer layer 22. Next, the sapphire substrate 21 is irradiated from the rear thereof with excimer laser light of approximately 300 nm or less at several hundreds mJ/cm² to decompose the GaN buffer layer 22, so that the sapphire substrate 21 is peeled off. This method is called laser lift-off (hereinafter, abbreviated as LLO) (for example, see patent document 1).

When the sapphire substrate 21 is irradiated from the rear thereof with the laser light, the GaN buffer layer 22 absorbs the laser light and is decomposed into Ga and N, thereby generating N₂ gas. However, since the isolation trench 24 is formed, the N₂ gas is exhausted from the isolation trench 24. Thereby, the isolation trench 24 also plays a role in preventing excessive stress caused by the N₂ gas from being applied to the crystal layer of the nitride semiconductor 23.

Patent document 1: JP-A 2003-168820

### DISCLOSURE OF THE INVENTION

### Problems to be Solved by the Invention

However, in the above-mentioned conventional method, the isolation trench 24 needs to be formed to reach the sapphire substrate 21, in either cases of the structure where the two electrodes of the p type and the n type are provided on the same surface side of the sapphire substrate, or of the structure where the sapphire substrate is peeled off to face the n electrode and the p electrodes face each other. Therefore, time required for dry etching is long, and accordingly, time during which side surfaces of the light emitting region of the nitride semiconductor 23 are exposed to etching gas (plasma) is long. As a consequence, the light emitting region is damaged to cause an increase in leakage current, ESD deterioration due to this, and luminance deterioration.

The present invention is made to solve the problems mentioned above, and an object thereof is to provide a method for manufacturing a nitride semiconductor light emitting element. By this method, when an isolation trench for chip isolation and for laser lift-off is formed, a degradation-free nitride semiconductor light emitting element with high luminance can be formed without doing any damages to a light emitting region.

### Means for Solving the Problems

In order to achieve the above-mentioned object, the invention according to claim 1 is a method for manufacturing a nitride semiconductor device including: a nitride laminated structure body stacked on a growth substrate, the nitride laminated structure body including GaN and having at least an n type nitride semiconductor layer, a light emitting region, and a p type nitride semiconductor layer in a sequential order; and an isolation trench formed in the nitride laminated structure body. The method is characterized by including: forming a first isolation trench from the n type nitride semiconductor layer beyond the light emitting region by using dry etching with gas including chlorine; and forming a second isolation trench being continuous with the first isolation trench and reaching the growth substrate, by using laser with a wavelength that is transparent to the growth substrate and is absorbed in the nitride laminated structure body.

Furthermore, the invention according to claim 2 is the method for manufacturing a nitride semiconductor light emitting element according to claim 1, the method characterized by further including, after the formation of the first isolation trench, removing, by electrochemical etching, damages on side surfaces of the nitride laminated structure body caused by the dry etching.

Furthermore, the invention according to claim 3 is the method for manufacturing a nitride semiconductor light emitting element according to any one of claims 1 and 2, the method being characterized by further including, after the formation of the first isolation trench, forming a protective insulating film on the side surfaces of the nitride laminated structure body along the first isolation trench. Also, the method is characterized in that the second isolation trench is formed after the formation of the protective insulating film.

Furthermore, the invention according to claim 4 is the method for manufacturing a nitride semiconductor light emitting element according to any one of claims 1 to 3, the method being characterized in that the laser used to form the second isolation trench has a wavelength of not more than 360 nm.

Furthermore, the invention according to claim 5 is the method for manufacturing a nitride semiconductor light emitting element according to claim 4, the method being characterized in that the laser used to form the second isolation trench is any one of KrF, XeCl, YAG fourth harmonic, and Ti-sapphire third harmonic.

### EFFECT OF THE INVENTION

According to the present invention, as for an isolation trench for chip isolation or for laser lift off, a first isolation trench from a light emitting region beyond an n type nitride semiconductor layer is formed by using dry etching, and a second isolation trench is formed so as to be continuous with the first isolation trench and to reach a growth substrate, by using laser light. Therefore, the light emitting region and the like are not exposed to etching gas (plasma) for a long time. Accordingly, damages to the light emitting region and the like can be reduced.

Additionally, a protective insulating film is formed on side surfaces of a nitride laminated structure body along the first isolation trench formed by using the dry etching, and the second isolation trench that reaches the growth substrate is formed thereafter. Accordingly, damages to the light emitting region and the like caused by laser irradiation can be prevented.

### BRIEF DESCRIPTION OF THE DRAWINGS

FIG. 1 is a drawing showing a cross-sectional structure of a first nitride semiconductor light emitting element according to the present invention.

FIG. 2 is a drawing showing a cross-sectional structure of a second nitride semiconductor light emitting element according to the present invention.

FIG. 3 is a drawing showing a manufacturing process of the first nitride semiconductor light emitting element.

FIG. 4 is a drawing showing the manufacturing process of the first nitride semiconductor light emitting element.

FIG. 5 is a drawing showing the manufacturing process of the first nitride semiconductor light emitting element.

FIG. 6 is a drawing showing the manufacturing process of the first nitride semiconductor light emitting element.

FIG. 7 is a drawing showing the manufacturing process of the first nitride semiconductor light emitting element.

FIG. 8 is a drawing showing the manufacturing process of the first nitride semiconductor light emitting element.

FIG. 9 is a drawing showing a manufacturing process of the second nitride semiconductor light emitting element.

FIG. 10 is a drawing showing the manufacturing process of the second nitride semiconductor light emitting element.

FIG. 11 is a drawing showing the manufacturing process of the second nitride semiconductor light emitting element.

FIG. 12 is a drawing showing the manufacturing process of the second nitride semiconductor light emitting element.

FIG. 13 is a drawing showing the manufacturing process of the second nitride semiconductor light emitting element.

FIG. 14 is a drawing of a nitride semiconductor light emitting element formed without peeling off a growth substrate.

FIG. 15 is a drawing showing manufacturing process of a conventional nitride semiconductor light emitting element.

### EXPLANATION OF REFERENCE NUMERALS

1 n electrode
2 n type nitride semiconductor layer
3 active layer
4 p type nitride semiconductor layer
5 p electrode
6 reflecting film
7 conductive fusing layer
8 supporting substrate
9 protective insulating film
11 sapphire substrate
12 GaN buffer layer
13 mask
14 mask
15 p side pad electrode
16 wire
17 n side pad electrode
18 contact hole
21 sapphire substrate
22 GaN buffer layer
23 nitride semiconductor
24 isolation trench
61 reflecting film

### BEST MODE FOR CARRYING OUT THE INVENTION

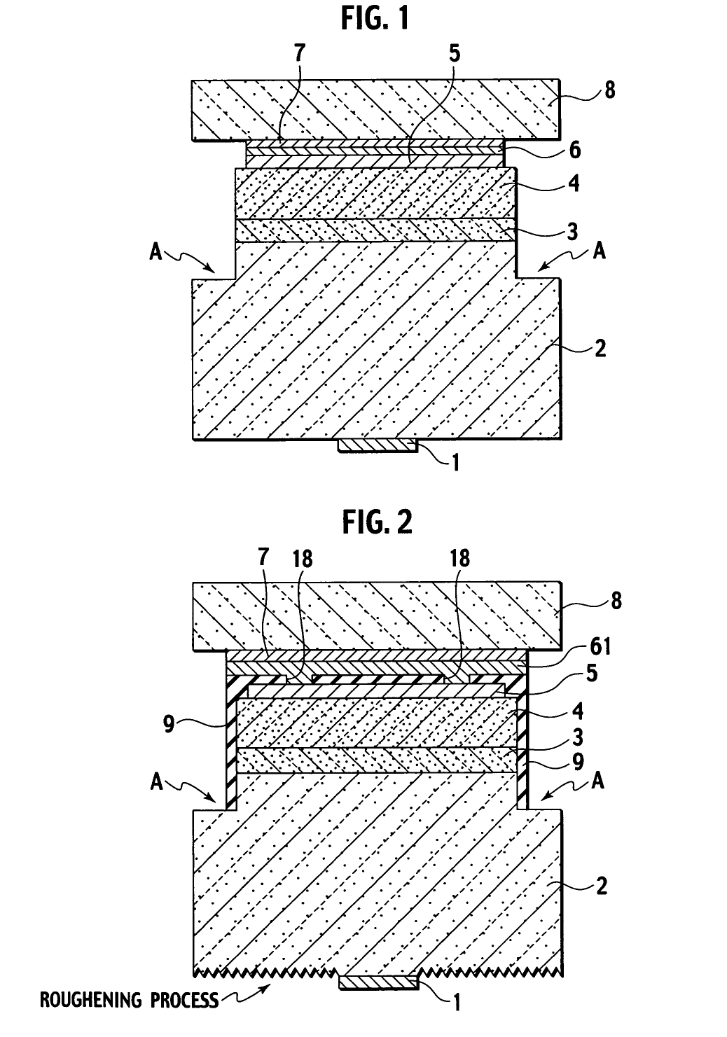

Hereinafter, with reference to the drawings, an embodiment of the present invention will be described. FIG. 1 shows a cross-sectional structure of a first nitride semiconductor light emitting element according to the present invention.

The nitride semiconductor, which is also known as a group III-V semiconductor, has an element, such as Al, Ga, and In, selected from III group in the periodic table, and an element N from V group. The nitride semiconductor may be a binary mixed crystal such as gallium nitride (GaN), may be a ternary mixed crystal such as aluminum gallium nitride (AlGaN) and indium aluminum nitride (InGaN), or may be a quaternary mixed crystal such as aluminum gallium indium nitride (AlGaInN). By disposing these materials on a substrate, a laminated semiconductor structure that can be used as a light emitting element used for photoelectric devices is manufactured. The nitride semiconductor has a wide band gap needed for light emission of visible light with a short wavelength of green-blue-purple-ultraviolet spectrum.

Although a ternary mixed crystal of InGaN is used in the present example, the materials are not limited to InGaN as mentioned above. An n type nitride semiconductor layer 2 and a p type nitride semiconductor layer 4 are formed to sandwich an active layer 3 as a light emitting region, and therefore, a double hetero structure is provided. The active layer 3 has a multiple quantum-well structure formed of, for example, InGaN/GaN. InGaN as a well layer and undoped GaN as a barrier layer (barrier layer) are alternately laminated. Here, InGaN made of 0.5 to 2% of In composition can be also used for the barrier layer. Incidentally, while the active layer 3 is provided as the light emitting region, a direct p-n junction of the n type nitride semiconductor layer 2 and the p type nitride semiconductor layer 4 may be formed without providing the active layer 3. In this case, a p-n junction interface part serves as the light emitting region.

The n type nitride semiconductor layer 2 is formed of, for example, a GaN contact layer doped with an n type impurity Si and an InGaN/GaN superlattice layer doped with an n type impurity Si laminated on the GaN contact layer. The superlattice layer eases stress of InGaN and GaN, the lattice constant difference between which is large, and facilitates growth of InGaN in the active layer. On the other hand, the p type nitride semiconductor layer 4 is formed of, for example, a GaN contact layer doped with a p type impurity Mg. An n electrode 1 is formed on the underside of the n type nitride semiconductor layer 2, and a p electrode 5 is formed on the p type nitride semiconductor layer 4. The n electrode 1 is formed of a laminated body of Ti and Al or of Al or the like, and is in ohmic contact with the n type nitride semiconductor layer 2. A laminated body of Ni and Au, or the like can be used for the p electrode 5. However, in the case of a structure where light extraction efficiency is taken into consideration, the p electrode 5 is desirably a transparent electrode, and for example, it can be an electrode in ohmic contact using Ga doped ZnO.

A reflecting film 6 is provided to reflect light generated in the active layer 3 so as to extract the light toward the n electrode 1. Silver gray metals such as Al and Ag that work as a reflective mirror are used for the reflecting film 6. In this case, the p electrode 5 is desirably a transparent electrode, and the Ga doped ZnO electrode mentioned above is used. A lattice constant of Ga doped ZnO approximates to that of GaN. Accordingly, when a p type GaN contact layer is used for the p type nitride semiconductor layer 4, the Ga doped ZnO electrode forms satisfactory ohmic contact with the p type GaN contact layer without performing subsequent annealing.

A conductive fusing layer 7 bonds the reflecting film 6 and a supporting substrate 8 together. The conductive fusing layer 7 may be wax materials such as solder. Or, when thermocompression bonding, a multi-layered metal film of Ti and Au or Au alone is used, or a multi-layered metal film of an alloy of Au and Sn and Ti is used. The conductive fusing layer 7 electrically connects the p electrode 5 with the supporting substrate 8 through the reflecting film 6. The supporting substrate 8 is used to apply (transfer) the nitride semiconductor grown on the sapphire substrate, and a conductive substrate is often used. Materials such as GaN, silicon, and SiC are used as the conductive substrate, while Cu, AlN, or the like is also used as a submount with high thermal conductivity. The supporting substrate made of AlN is an insulating substrate, which provides an advantage when a chip is mounted on circuits such as printed circuit boards. When the supporting substrate 8 is a conductive substrate, an external connection terminal or the like is provided on the supporting substrate 8 on a side opposite to where the conductive fusing layer 7 is formed, so as to be connected with an external electric terminal.

Incidentally, in the n type nitride semiconductor layer 2, a step A is formed in a region beyond the active layer 3 looked from the p side. A first isolation trench is formed up to the step A portion by using gas including chlorine such as Cl₂ gas or SiCl₄ gas and performing mesa etching with an ICP (Induced Coupled Plasma: inductive coupling type) etcher or the like. A second isolation trench is formed below the step A (direction toward the n electrode 1) by etching using laser with a wavelength that is transparent to a growth substrate and is absorbed in the GaN-based semiconductor layer on the growth substrate.

Since the formation of the second isolation trench is performed not by dry etching but by etching with laser light, a part of the n type nitride semiconductor layer 2, the active layer 3, and the p type nitride semiconductor layer 4, and the like are not exposed to etching gas (plasma) for a long time, thus allowing prevention of deterioration of the light emitting region and the like.

FIG. 2 shows a cross-sectional structure of a second nitride semiconductor light emitting element according to the present invention. Components to which the same numbers as those in FIG. 1 are given have the same structures as those in FIG. 1. As shown in FIG. 2, a protective insulating film 9 covers side surfaces of a chip above a position of the step A. With this configuration, when an isolation trench for isolating each element or an isolation trench for exhausting therethrough N₂ gas generated by LLO are formed, a part of the n type nitride semiconductor layer 2, the active layer 3 that is a light emitting region, and the p type nitride semiconductor layer 4 are protected by the protective insulating film 9. Therefore, damages due to etching with laser light can be prevented. For example, in the case of light emitting diode elements, the protective insulating film 9 is annularly formed in a periphery of the chip, while in the case of semiconductor lasers, the protective insulating film 9 is formed on both side surfaces of the chip in order to obtain a resonator structure. SiN, SOG (Spin On Glass), or the like are used for the protective insulating film 9.

Light generated in the active layer 3 of the nitride semiconductor light emitting element with a configuration of FIG. 2 is extracted in a direction toward the n electrode 1 (downward direction in the drawing). A refractive index of the protective insulating film 9 is made smaller than each refractive index of the n type nitride semiconductor layer 2, the active layer 3, and the p type nitride semiconductor layer 4, so that part of the light emitted from inside toward the side surfaces of the element is totally reflected at an interface of each semiconductor layer and the protective insulating film 9. Thereby, light extraction efficiency improves. Use of SiN and SOG for the protective insulating film 9, as mentioned above, makes the refractive index of the protective insulating film 9 smaller than the refractive index of each semiconductor layer including GaN.

In addition, a reflecting film 61 is provided, and silver gray metals such as Al and Ag that work as a reflective mirror are used in the same manner as in the case of FIG. 1. The reflecting film 61 not only reflects the light totally reflected from the protective insulating film 9 provided on the side surfaces, but also reflects the light that directs upward, thereby to extract the light in the direction toward the n electrode 1.

Incidentally, the reflecting film 61 is not directly laminated on the whole surface of the p electrode 5, but is formed so that a part of the reflecting film 61 may directly contact the p electrode 5 through a small contact hole 18. In other regions, the reflecting film 61 is formed with the protective insulating film 9 sandwiched in between. This is because when approximately the whole surface of the p electrode 5 is in contact with the reflecting film 61, the light would be absorbed between the p electrode 5 and the reflecting film 61, leading to reduction in reflectance. The silver gray metals such as Al and Ag form ohmic contact with the Ga doped ZnO, and presumably, attributed to this, the reflectance of the reflecting film 61 is impaired.

Therefore, as in FIG. 2, when the p electrode 5 is in contact with the reflecting film 61 only through the contact hole 18, the light is absorbed only in the contact hole 18, thereby maintaining high reflectance.

Moreover, while a light extracting surface (surface on the side of the n electrode 1) of the n type nitride semiconductor layer 2 may be mirror-finished as shown in FIG. 1, the light extracting surface may have a roughened surface (surface in which depressions and projections are formed) as shown in FIG. 2 in order to enhance the light extraction efficiency. A critical angle exists because of a refractive index difference between the n type nitride semiconductor layer 2 and the atmosphere, and the emitted light having a larger incident angle than the critical angle cannot be totally reflected and extracted outside. For the reason, formation of the depressions and projections causes increase in a proportion that the incident angle becomes smaller than the critical angle, thereby improving the light extraction efficiency.

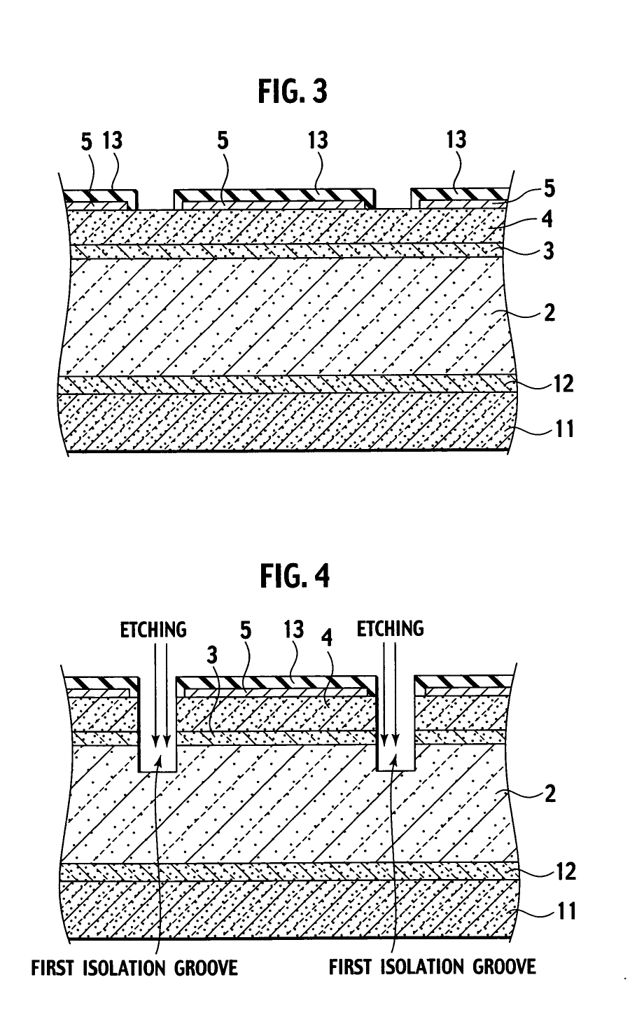

Hereinafter, a method for manufacturing the first nitride semiconductor light emitting element of the present invention will be described using FIGS. 3 through 8. At first, description is given with reference to FIG. 3. First, as a growth substrate, a sapphire substrate 11 is placed in an MOCVD (metal organic chemical vapor deposition) apparatus. With hydrogen gas flown, a temperature is raised to approximately 1050° C., so as to thermally clean the sapphire substrate 11. Then, the temperature is lowered to approximately 600° C., and a GaN buffer layer 12 to be used as an isolating layer is grown at a low temperature.

Alternatively, the above-mentioned initial process can be performed as follows. For example, the sapphire substrate 11 is placed in a PLD (Pulsed Laser Deposition) apparatus, and the sapphire substrate 11 is cleaned at 600 to 800° C. without introducing gas. GaN may be targeted and ablated by KrF laser so that the GaN buffer layer 12 made of GaN single crystal is grown. Subsequently, the sapphire substrate 11 is carried into the MOCVD apparatus, and film formation is performed in the same manner as below.

The temperature within the MOCVD apparatus is again raised to approximately 1000° C., and the n type nitride semiconductor layer 2 is laminated on the GaN buffer layer 12. The n type nitride semiconductor layer 2 is formed with, for example, a laminated structure made of a GaN contact layer doped with an n type impurity Si and an InGaN/GaN superlattice layer doped with the n type impurity Si. Therefore, the GaN contact layer doped with the n type impurity Si is grown on the GaN buffer layer 12 first, and then, the InGaN/GaN superlattice layer doped with the n type impurity Si are further grown thereon.

Next, the active layer 3 is formed. As an example, an MQW layer (multiple quantum well structure layer) with InGaN/GaN is used for the active layer 3. By alternately laminating, as a well layer, In0.17GaN of 20 to 40 Å, desirably, 25 to 35 Å, and, as a barrier layer, an undoped GaN layer or an InGaN layer of 50 to 300 Å, desirably, 100 to 200 Å having approximately 1% of In composition, a multilayer structure of, for example, 5-period to 8-period, desirably, 3-period to 10-period is grown. Incidentally, in an InGaN well layer having a higher ratio of In composition, In sublimates at a high temperature and becomes easy to break. Accordingly, the undoped GaN layer that has a role of a cap layer, or the InGaN layer made of approximately 1% of In composition is laminated on the active layer 3. Subsequently, the temperature is raised, and the p type nitride semiconductor layer 4 is grown. The p type nitride semiconductor layer 4 is formed of, for example, a GaN contact layer doped with a p type impurity Mg, or the like.

Next, when a Ga doped ZnO electrode, for example, is used as the p electrode 5, the Ga dope ZnO electrode having a low resistivity of approximately 2e⁻⁴ Ωcm is laminated using the molecular beam epitaxy method, and is etched according to a shape of a chip. A mask 13 is formed according to the shape of the chip by using a dielectric film such as SiO₂ or a resist.

Next, as shown in FIG. 4, the first isolation trench is formed by performing mesa etching. The mesa etching is performed with an ICP (Induced Coupled Plasma: inductive-coupling type) etcher or the like by using gas including chlorine such as Cl₂ gas or SiCl₄ gas. The mesa etching is performed, passing through the active layer 3, to a place where the n type GaN contact layer in the n type nitride semiconductor layer 2 is exposed, and then, etching is once stopped.

When dry etching with the above-mentioned gas including chlorine is performed at this point, a leak path is generated on side surfaces of the nitride laminated structure body, that is, across the p type nitride semiconductor layer 4, the active layer 3, and a part of n the type nitride semiconductor layer 2. Therefore, this damage may be removed using electrochemical etching. As an example of the electrochemical etching, the nitride laminated structure body is dipped in strong alkalis such as NaOH and KOH, and UV light having a wavelength not less than band gap energy of the active layer 3 is applied, thereby removing the damage of the leak path.

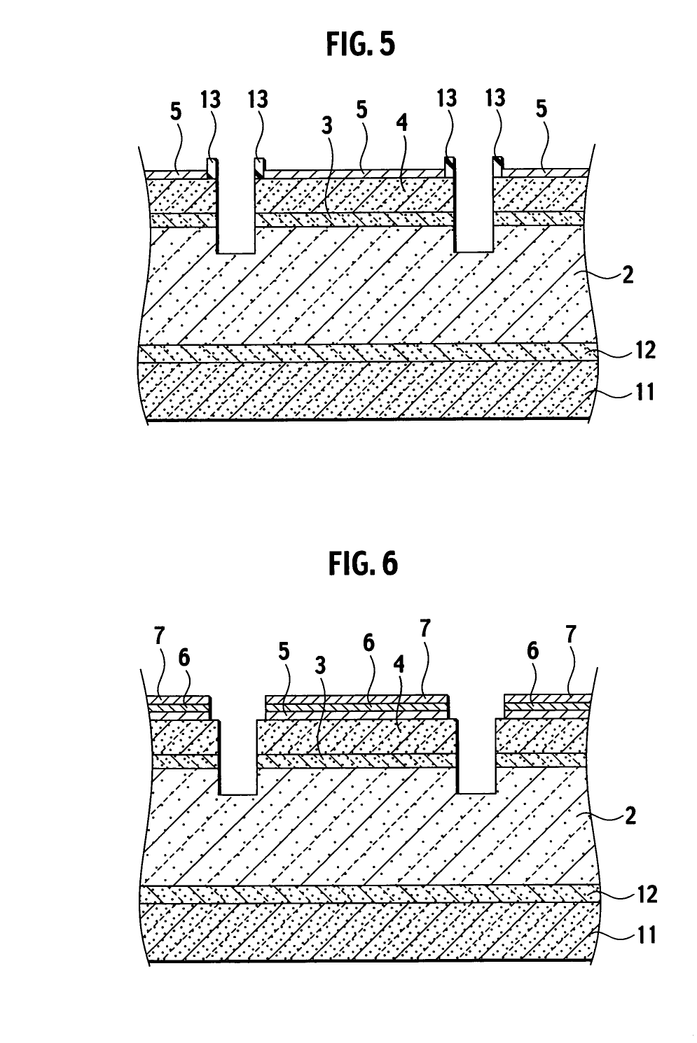

As shown in FIG. 5, the mask 13 is lifted off so as to enable film formation on the p electrode 5. As shown in FIG. 6, the reflecting film 6 that works as a reflective mirror of silver gray metals such as Al and Ag is laminated on the p electrode 5 with vacuum deposition method, and the conductive fusing layer 7 is laminated thereon. The conductive fusing layer 7 is formed of Ti/Au or Au alone or the like with vacuum deposition method. At this time, it is preferable that, after vapor-depositing Au, patterning be performed in accordance with the shape of the chip so as to perform plating with several μm of Au with electric field plating. The mask 13 is removed after the metal formation of the reflecting film 6 and the conductive fusing layer 7.

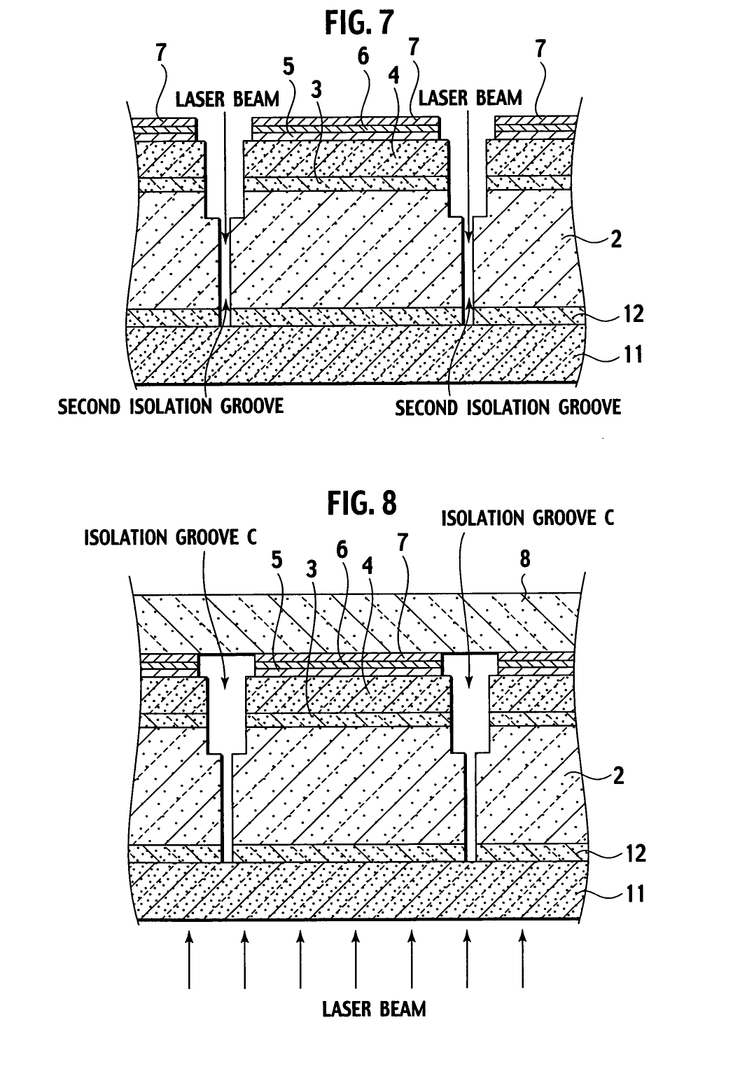

As shown in FIG. 7, the etching that has been stopped in the process of FIG. 4 is resumed to form the first isolation trench by etching until the sapphire substrate 11 is exposed. In formation of the second isolation trench, unlike formation of the first isolation trench of FIG. 4, etching is performed by irradiating between mesas (the isolation trench) with KrF laser oscillated at 248 nm at an energy fluence of not less than 1 mJ, and by scanning, and the etching is performed until the sapphire substrate 11 is exposed. The etching by laser is performed using the laser with a wavelength that transmits through (is transparent to) the growth substrate (sapphire substrate 11) without being absorbed by the growth substrate, and is absorbed by the nitride laminated structure body including GaN on the growth substrate. The laser light is absorbed by, for example, GaN included in the n type nitride semiconductor layer 2, and a temperature of GaN rises so that GaN decomposes into Ga and N, thereby performing etching.

Moreover, since etching by the laser, unlike dry etching, does not cause damages to the light emitting region and the like, etching by the laser is ideal as etching to form the second isolation trench. Besides, since its etching rate is faster (not less than 5 μm/min.) than that in dry etching, time needed for manufacturing process can be shortened.

In addition to the above-mentioned KrF laser oscillated at 248 nm, the laser used for etching and having the wavelength that is transparent to the sapphire substrate 11 and is absorbed in the GaN system semiconductor layer on the growth substrate includes XeCl: 308 nm; YAG (yttrium aluminum garnet) fourth harmonic: 266 nm; Ti-Sapphire (sapphire) third harmonic: 360 nm. These are used.

As shown in FIG. 8, after completion of etching, the supporting substrate 8 is disposed at a topmost part of a grown layer on the growth substrate (sapphire substrate 11), and is affixed onto a laminated body shown in FIG. 8 by the conductive fusing layer 7 using thermocompression bonding or the like. The thermocompression bonding is performed at approximately 400° C. Sandwiching the supporting substrate 8 and the laminated body with a jig made of carbon is preferred. This is because carbon has small thermal expansion, and while a space of the carbon jig remains as it is, the laminated body and the supporting substrate 8 formed on the growth substrate both expand, thereby allowing compression bonding therebetween.

Here, an isolation trench C=the first isolation trench+the second isolation trench is shown. The trench width of the second isolation trench is smaller than that of the first isolation trench shown in FIG. 4. The isolation trench C has a role of an isolation trench that isolates each element (each chip), and has another role of exhausting N₂ gas therethrough to prevent crack of the nitride semiconductor layer, the N₂ gas being generated due to decomposition of the GaN buffer layer 12 when LLO is used to remove the sapphire substrate 11.

Next, when the sapphire substrate 11 is removed using LLO, as shown in FIG. 8, the KrF laser oscillated at 248 nm is applied in the direction from the sapphire substrate 11 side to the GaN buffer layer 12, so that the sapphire substrate 11 is peeled off. In addition to the KrF, the usable laser includes ArF: 193 nm; XeCl: 308 nm; YAG third harmonic: 355 nm; Ti-Sapphire third harmonic: 360 nm; He—Cd: 325 nm, or the like.

In the case of the KrF, needed irradiation energy is 50 to 500 mJ/cm², and desirably, 100 to 400 mJ/cm². Since the light of 248 nm almost completely transmits through the sapphire substrate 11 and is absorbed approximately 100% in the GaN buffer layer 12, a temperature rapidly rises at an interface of the sapphire substrate 11 and the GaN buffer layer 12, thus resulting in decomposition of GaN in the GaN buffer layer 12. Since N₂ generated at this time escapes to an opening of the isolation trench C, cracks can be effectively prevented with no pressure applied to the nitride semiconductor layer.

After the peeling-off of the sapphire substrate 11, excessive Ga is drained using acid etching or the like, and the n electrode 1 is formed. The n electrode 1 is formed of a multi-layered metal film, made of Al/Ni/Au, Al/Pd/Au, Ti/Al/Ni/Au, Ti/Al/Ti/Au, and the like, and an ohmic contact is taken.

Then, the supporting substrate 8 is cut to be separated into chip-shaped pieces by dicing or the like, and the nitride semiconductor light emitting element of FIG. 1 is completed.

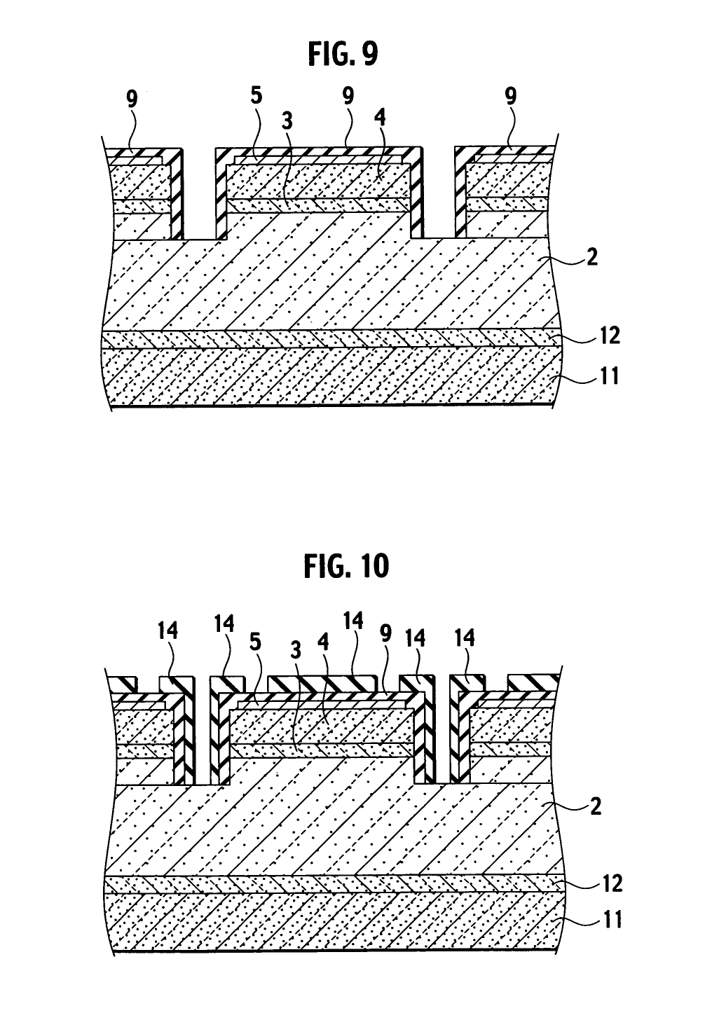

Next, hereinafter, a method for manufacturing the second nitride semiconductor light emitting element shown in FIG. 2 will be described using FIGS. 9 through 13.

First, manufacturing is carried out in the same manner as the method for manufacturing the first nitride semiconductor light emitting element in accordance with the process from FIGS. 3 to 4. After removal of the mask 13 used for forming the first isolation trench, as shown in FIG. 9, the protective insulating film 9 is formed by P-CVD or sputtering to completely cover from an upper surface of the p electrode 5 to a lower end of the first isolation trench. Here, a space between adjacent elements is fully provided so that an inside of the first isolation trench may not be filled up. The protective insulating film 9 is annularly formed in a periphery of a chip in the case of light emitting diode elements, and is formed in both side surfaces of the chip in order to obtain a resonator structure in the case of semiconductor lasers. Then, as shown in FIG. 10, a mask 14, formed of a dielectric film such as SiO or a resist, is patterned according to a shape of a contact hole.

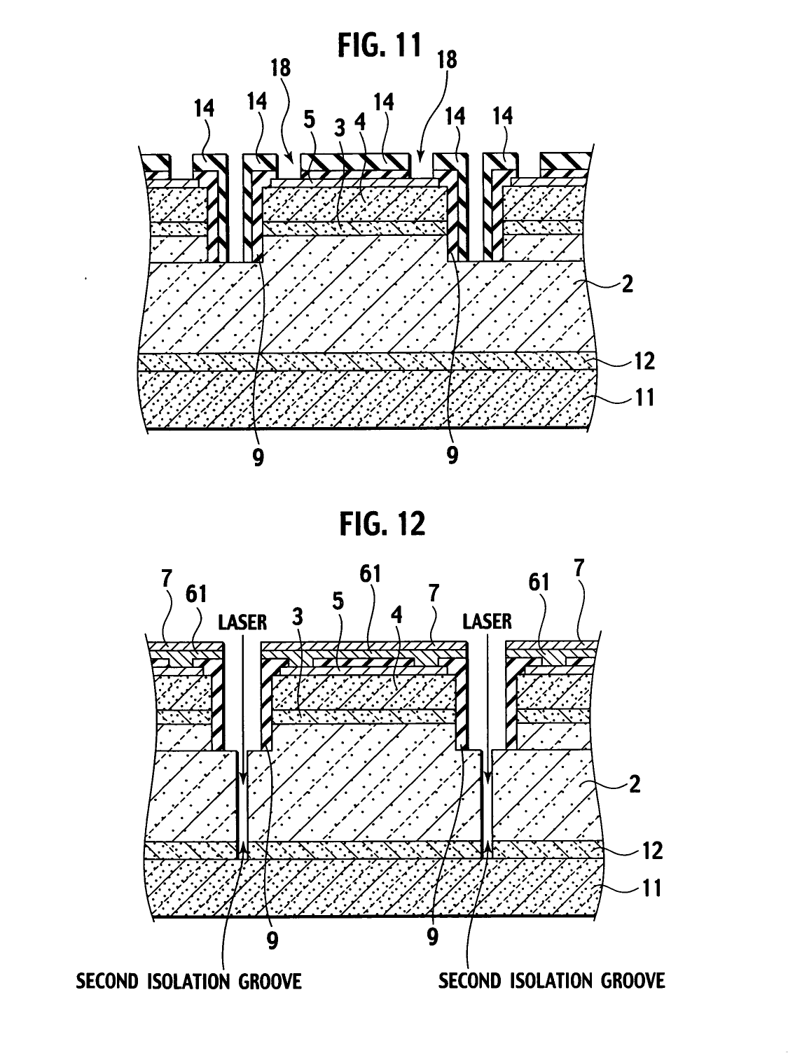

Next, as shown in FIG. 11, CF4 dry etching is performed to remove the protective insulating film 9 corresponding to a region of the contact hole 18, so as to form the contact hole 18 for the p electrode 5. A ZnO electrode is used for the p electrode 5 in the present example. In the CF4 dry etching, an etching rate of ZnO is slower than that of the protective insulating film 9, and accordingly, ZnO itself functions as an etch stop.

After the formation of the contact hole, the reflecting film 61 and the conductive fusing layer 7 are formed by the vacuum deposition method. As shown in FIG. 11, etching that has been stopped in the process of FIG. 4 is resumed to form the second isolation trench by etching until a sapphire substrate 11 is exposed. In the same manner as in the case of FIG. 7 mentioned above, this etching is performed using the laser with a wavelength that is transparent to the growth substrate (sapphire substrate 11) and is absorbed in the GaN system semiconductor layer on the growth substrate. For example, etching is performed by irradiating between mesas (the isolation trench) with KrF laser oscillated at 248 nm at an energy fluence of not less than 1 mJ, and by scanning, and the etching is performed until the sapphire substrate 11 is exposed. In addition to this, XeCl: 308 nm; YAG fourth harmonic: 266 nm; Ti-Sapphire (sapphire) third harmonic: 360 nm, or the like can be also used.

During the etching by the laser mentioned above, the active layer 3 as a light emitting region, the p type nitride semiconductor layer 4, and the like, that is, regions in which the protective insulating film 9 is already provided are protected from the laser irradiation, thereby preventing deterioration. The trench width of the second isolation trench is made smaller than that of the first isolation trench shown in FIG. 4. Here, the isolation trench C=the first isolation trench+the second isolation trench is shown.

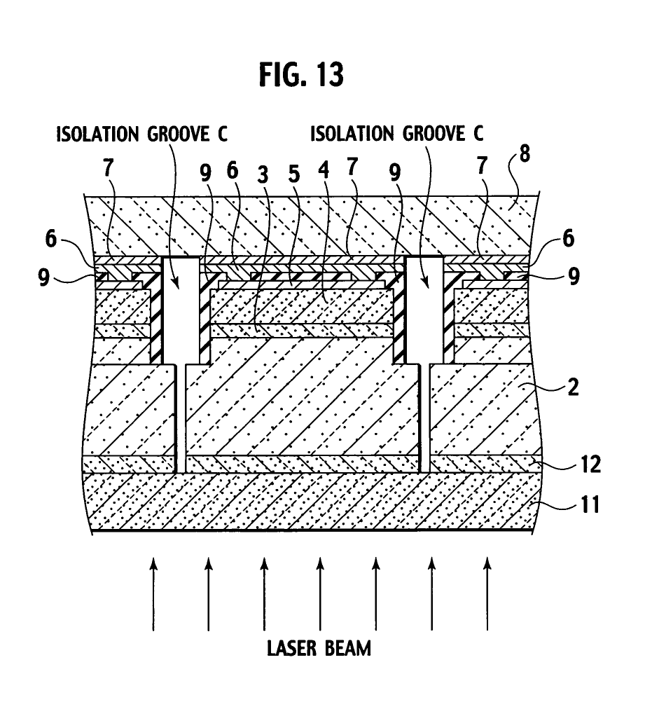

As shown in FIG. 13, after completion of the etching, the supporting substrate 8 is disposed at a topmost part of a grown layer on the growth substrate (sapphire substrate 11), and is affixed onto the laminated body shown in FIG. 2 by the conductive fusing layer 7 using thermocompression bonding or the like. As described in FIG. 8, compression bonding can be made by performing thermocompression bonding at approximately 400° C., and sandwiching the supporting substrate 8 and the laminated body with the jig made of carbon.

Next, when the sapphire substrate 11 is removed using LLO, in the same manner as in the case of FIG. 8, the KrF laser oscillated at 248 nm, for example, is applied in a direction from the sapphire substrate 11 side to the GaN buffer layer 12 so that the sapphire substrate 11 is peeled off. Although decomposition of GaN generates N₂ at this time, the N₂ escapes to an opening of the isolation trench C. Therefore, cracks can be effectively prevented with no pressure applied to the nitride semiconductor layer. In addition to the KrF, the usable laser includes ArF: 193 nm; XeCl: 308 nm; YAG third harmonic: 355 nm; Ti-Sapphire third harmonic: 360 nm; He—Cd: 325 nm, or the like.

After the peeling-off of the sapphire substrate 11, excessive Ga is drained by acid etching or the like, and then, the n electrode 1 is formed. The n electrode 1 is formed of a multi-layered metal film, made of Al/Ni/Au, Al/Pd/Au, Ti/Al/Ni/Au, Ti/Al/Ti/Au, or the like, and an ohmic contact is taken. As for roughening processing, before the formation of the n electrode 1 in the manufacturing process of FIG. 13, a portion of a region where the n electrode 1 is to be laminated is covered with a mask such as SOG and SiN. Then, etching is performed using KOH and UV light including a wavelength of 365 nm, so as to form depressions and projections on an exposed surface of the n type nitride semiconductor layer 2. Next, the mask is peeled off, and the n electrode 1 is formed.

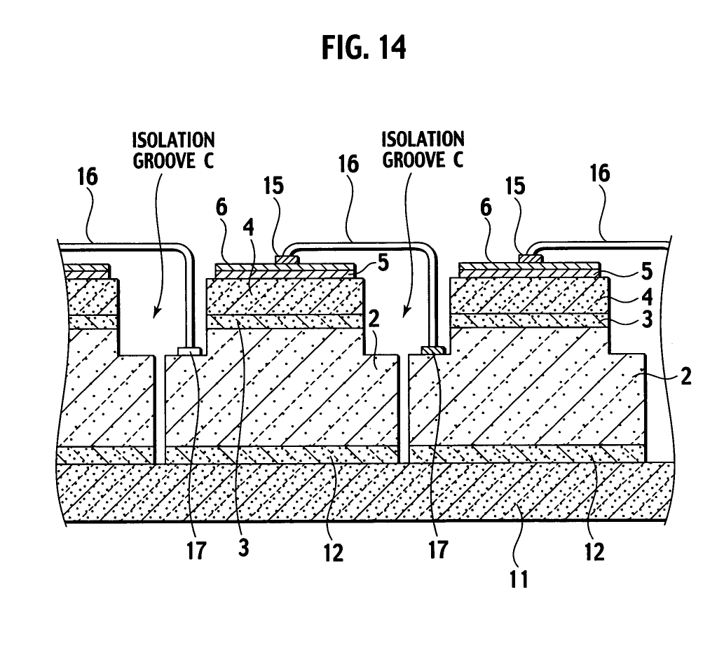

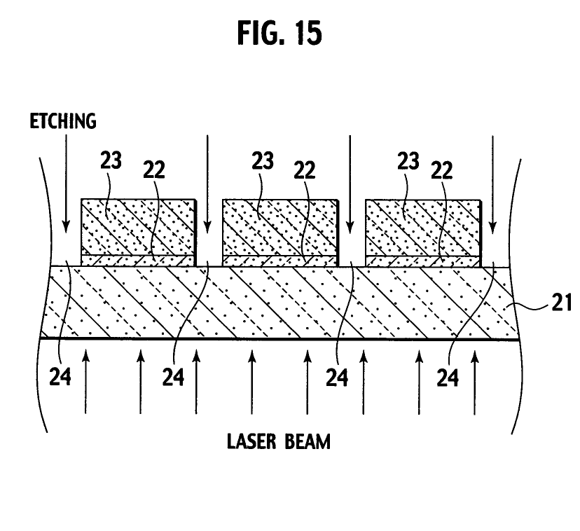

Incidentally, while the first and second nitride semiconductor light emitting elements have the structure in which the sapphire substrate is peeled off and the n electrode and the p electrode are provided to face each other, the first and second nitride semiconductor light emitting elements can also have a structure where two electrodes of a p type and an n type are provided on the same surface side on the sapphire substrate. FIG. 14 shows an example of such a configuration. In the process of FIG. 4, the width of the first isolation trench is formed to be wider. Without laminating the conductive fusing layer 7 in the process of FIG. 6, the second isolation trench is formed to separate into chip-shaped pieces in the process of FIG. 7. Then, without affixing the supporting substrate 8 shown in FIG. 8, a p side pad electrode 15 is provided on an upper portion of a reflecting electrode 6 of each chip, with the sapphire substrate 11 (growth substrate) being bonded.

On the other hand, an n side pad electrode 17 is formed on a lowermost layer of each chip of the n type nitride semiconductor layer 2 exposed by the mesa etching performed in the process of forming the first isolation trench in FIG. 4, in this present example, for example, on an n-GaN contact layer. A wire 16 wire-bonded to the p side pad electrode 15 is connected with the n side pad electrode 17 of an adjacent chip. Thereby, individual chips are connected in series, and a line-shaped light emitting element or two-dimensional light emitting element can be obtained. In this case, light generated is extracted through the bottom side of the sapphire substrate 11.

1. A method for manufacturing a nitride semiconductor device including: a nitride laminated structure body stacked on a growth substrate, the nitride laminated structure body including GaN and having at least an n type nitride semiconductor layer, a light emitting region, and a p type nitride semiconductor layer in a sequential order; and an isolation trench formed in the nitride laminated structure body, the method characterized by comprising:
forming a first isolation trench from the n type nitride semiconductor layer beyond the light emitting region by using dry etching with gas including chlorine; and
forming a second isolation trench being continuous with the first isolation trench and reaching the growth substrate, by using laser with a wavelength that is transparent to the growth substrate and is absorbed in the nitride laminated structure body.

2. The method for manufacturing a nitride semiconductor light emitting element according to claim 1, characterized by further comprising, after the formation of the first isolation trench, removing, by electrochemical etching, damages on side surfaces of the nitride laminated structure body caused by the dry etching.

3. The method for manufacturing a nitride semiconductor light emitting element according to claim 2, characterized by further comprising, after the formation of the first isolation trench, forming a protective insulating film on the side surfaces of the nitride laminated structure body along the first isolation trench,
the method characterized in that the second isolation trench is formed after the formation of the protective insulating film.

4. The method for manufacturing a nitride semiconductor light emitting element according to claim 3, characterized in that the laser used for forming the second isolation trench has a wavelength of not more than 360 nm.

5. The method for manufacturing a nitride semiconductor light emitting element according to claim 4, characterized in that the laser used for forming the second isolation trench is any one of KrF, XeCl, YAG fourth harmonic, and Ti-sapphire third harmonic.

6. The method for manufacturing a nitride semiconductor light emitting element according to claim 1, characterized by further comprising, after the formation of the first isolation trench, forming a protective insulating film on the side surfaces of the nitride laminated structure body along the first isolation trench,
the method characterized in that the second isolation trench is formed after the formation of the protective insulating film.

7. The method for manufacturing a nitride semiconductor light emitting element according to claim 6, characterized in that the laser used for forming the second isolation trench has a wavelength of not more than 360 nm.

8. The method for manufacturing a nitride semiconductor light emitting element according to claim 2, characterized in that the laser used for forming the second isolation trench has a wavelength of not more than 360 nm.

9. The method for manufacturing a nitride semiconductor light emitting element according to claim 1, characterized in that the laser used for forming the second isolation trench has a wavelength of not more than 360 nm.

10. The method for manufacturing a nitride semiconductor light emitting element according to claim 9, characterized in that the laser used for forming the second isolation trench is any one of KrF, XeCl, YAG fourth harmonic, and Ti-sapphire third harmonic.

11. The method for manufacturing a nitride semiconductor light emitting element according to claim 8, characterized in that the laser used for forming the second isolation trench is any one of KrF, XeCl, YAG fourth harmonic, and Ti-sapphire third harmonic.

12. The method for manufacturing a nitride semiconductor light emitting element according to claim 7, characterized in that the laser used for forming the second isolation trench is any one of KrF, XeCl, YAG fourth harmonic, and Ti-sapphire third harmonic.
